(19) United States
(12) Patent Application Publication
(10) Pub. No.: US 2011/0298487 A1
(43) Pub. Date: Dec. 8, 2011

(54) SEMICONDUCTOR TESTING APPARATUS AND TESTING METHOD

(76) Inventors: Nobuhiro KATSUMA, Shiga (JP); Masatoshi WAKAMURA, Osaka (JP); Koji AKAHORI, Osaka (JP); Tomohiko KANEMITSU, Osaka (JP)

(21) Appl. No.: 13/156,039

(22) Filed: Jun. 8, 2011

(30) Foreign Application Priority Data
Jun. 8, 2010 (JP) 2010-130958

(51) Int. Cl. G01R 31/26

(52) U.S. Cl. 324/756.07

(57) ABSTRACT

An apparatus for testing electric characteristics of a semiconductor device having a plurality of hemispherical electrode terminals on one surface thereof, including: a support plate vertically movably supported by an elastic member, supporting a side of the one surface of the semiconductor device, and having through holes for accommodating the hemispherical electrode terminals; a probe pin securing block placed under the support plate; a plurality of probe pins secured to the probe pin securing block and having concave-shaped tips facing the hemispherical electrode terminals of the semiconductor device supported by the support plate; and a vertically movable pressing head placed over the support plate for applying a downward pressure on the support plate, wherein after the support plate is lowered by a predetermined amount by the downward pressure from the pressing head, the pressing head contacts the semiconductor device and applies a downward pressure thereon.

### CROSS-REFERENCE TO RELATED APPLICATION

This application claims priority to Japanese Patent Application No. 2010-130958 filed on Jun. 8, 2010, the disclosure of which including the specification, the drawings, and the claims is hereby incorporated by reference in its entirety.

### BACKGROUND

The present invention relates to a semiconductor testing apparatus and a testing method.

In recent years, as the functionality of semiconductor devices increases and as the size thereof decreases, the number of terminals of BGA-type package increases and the terminal pitch thereof decreases. Typically, in order to measure electric characteristics of a semiconductor device of the BGA-type package, a socket is used which electrically contacts the solder balls of the semiconductor device with probe pins so as to electrically connect a wiring substrate and the semiconductor device with each other. A reference example is a socket including a top plate 505 having a floating mechanism shown in FIG. 5, for example.

The socket includes a securing pin block 501 for holding a probe pin 508, the top plate 505 for positioning a semiconductor device 502, and a pressing mechanism 503 for pressing the semiconductor device 502. The top plate 505 positions the semiconductor device 502 with a concave-shaped guide portion that is slightly larger than the outer shape of the semiconductor device 502. Then, the surface of the semiconductor device 502 opposite to the solder ball surface thereof is pressed by using the pressing mechanism 503 so as to press it down together with the top plate 505 in the direction toward a wiring substrate 507, thereby contacting solder balls 520 of the positioned semiconductor device 502 with the probe pins 508 held by the securing pin block 501 and electrically connecting the solder balls 520 of the semiconductor device 502 and the probe pins 508 with each other.

In a semiconductor device with a narrow solder ball interval of a BGA-type package, in order to ensure an electric contact with a low contact resistance by stably contacting the probe pins with the solder balls of the semiconductor device, it is necessary to achieve high-precision positioning between the probe pins and the solder balls.

With the socket of this reference example, there is provided a clearance between the concave-shaped guide portion of the top plate for positioning the semiconductor device and the outer shape of the semiconductor device taking into consideration variations in the outer shape dimensions of the semiconductor device, and it is necessary to reduce the clearance between the concave-shaped guide portion of the top plate and the outer shape of the semiconductor device in order to enhance the semiconductor device positioning precision. However, if the clearance is reduced, the semiconductor device may get stuck in the guide portion of the top plate to prevent the solder balls from contacting the probe pins, due to variations in the outer shape dimensions of the semiconductor device. If the clearance of the guide portion is increased so as to avoid the stuck-in problem, it is not possible to increase the semiconductor device positioning precision.

In order to address such issues as described above, Japanese Laid-Open Patent Publication No. 2002-164136 discloses a method in which a semiconductor device is positioned after the semiconductor device is accommodated in a concave-shaped guide portion of a top plate. This method is a method in which the concave-shaped guide portion of the top plate is an adjustment member that can be adjusted with adjustment screws so that the semiconductor device is positioned after it seats on the top plate. However, to adjust the position of a semiconductor device by adjusting the adjustment member each time a semiconductor device seats on the top plate takes time and is not suitable for mass production.

### SUMMARY

The solder ball terminal pitch of BGA-type package semiconductor devices has been decreased recently as described above, and high-precision device positioning is required for reliably contacting the solder balls with the probe pins to ensure desirable electric contact therebetween. However, if the clearance of the guide portion of the top plate is narrowed in order to precisely position the device only with the concave-shaped guide portion provided in the top plate, the semiconductor device may get stuck in the top plate due to variations in the machining precision of the top plate and the outer shape dimensions of the device, etc.

In order to solve such a problem, an object of the present invention is to provide a semiconductor testing apparatus and a testing method with which it is possible to easily position a device with a high precision.

In order to achieve the object set forth above, a semiconductor testing apparatus of the present invention is a semiconductor testing apparatus for testing electric characteristics of a semiconductor device having a plurality of hemispherical electrode terminals on one surface thereof, including: a support plate vertically movably supported by an elastic member, supporting a side of the one surface of the semiconductor device, and having through holes for accommodating the hemispherical electrode terminals; a probe pin securing block placed under the support plate; a plurality of probe pins secured to the probe pin securing block and having concave-shaped tips facing the hemispherical electrode terminals of the semiconductor device supported by the support plate; and a vertically movable pressing head placed over the support plate for applying a downward pressure on the support plate, wherein after the support plate is lowered by a predetermined amount by the downward pressure from the pressing head, the pressing head contacts the semiconductor device and applies a downward pressure thereon.

In one embodiment, the pressing head includes a suction section for sucking onto a surface of the semiconductor device opposite to the one surface, and applies the downward pressure on the support plate after allowing the semiconductor device to fall onto the support plate by releasing suction.

In one embodiment, the support plate includes a main body portion on which the semiconductor device is placed, and a pressure-receiving portion which is attached to the main body portion and to be in contact with the pressing head to receive the downward pressure, and the pressure-receiving portion maintains a gap between the pressing head and the semiconductor device while the main body portion is lowered by the predetermined amount by receiving the downward pressure from the pressing head.

In one embodiment, the pressing head includes a first pressing portion to be in contact with the support plate for pressing down the support plate, and a second pressing portion to be in contact with the semiconductor device for applying a downward pressure on the semiconductor device, and the first pressing portion maintains a gap between the second pressing portion and the semiconductor device while the support plate is lowered by the predetermined amount.

In one embodiment, the pressure-receiving portion includes a positioning mechanism with respect to the pressing head.

A testing method of the present invention is a testing method using the semiconductor testing apparatus set forth above, including the steps of: placing the semiconductor device on the support plate so that the hemispherical electrode terminals are accommodated in the through holes; (A) lowering the support plate by applying a pressure thereon using the pressing head while maintaining a gap between the pressing head and the semiconductor device; and applying a downward pressure on the semiconductor device using the pressing head so as to ensure an electric conduction between the probe pins and the hemispherical electrode terminals, wherein in the step (A), the semiconductor device is moved horizontally so that the hemispherical electrode terminals fit into the concave-shaped tips of the probe pins.

### BRIEF DESCRIPTION OF THE DRAWINGS

FIG. 1 is a schematic cross-sectional view showing an exemplary configuration of a semiconductor testing apparatus of Embodiment 1.

FIGS. 2A-2D are schematic diagrams showing a part of the process of Embodiment 1.

FIG. 3 is a schematic cross-sectional view showing an exemplary configuration of a semiconductor testing apparatus of Embodiment 2.

FIGS. 4A-4D are schematic diagrams showing a part of the process of Embodiment 2.

FIG. 5 is a schematic cross-sectional view showing an exemplary configuration of a semiconductor testing apparatus of a reference example.

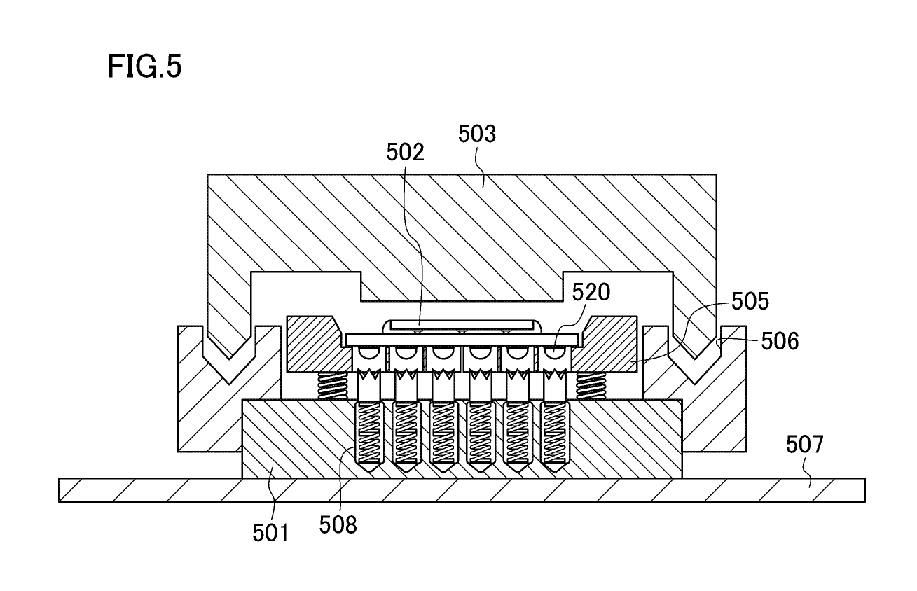

FIG. 6 is a schematic cross-sectional view showing another exemplary configuration of a semiconductor testing apparatus of Embodiment 1.

### DETAILED DESCRIPTION

Embodiments of the present invention will now be described with reference to the drawings.

### Embodiment 1

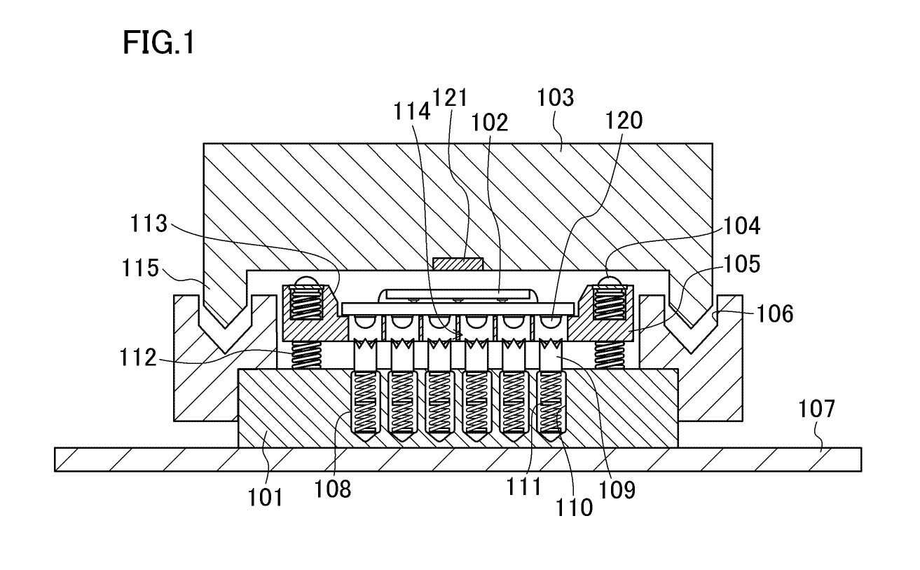

FIG. 1 shows a socket (semiconductor testing apparatus) used when measuring, with a measurement apparatus, electric characteristics of a semiconductor device 102. The socket includes probe pins 108, a pin securing block 101 for holding the probe pins 108, a top plate (support plate) 105 including a floating mechanism, and a pressing head 103 placed above the securing block 101 for pressing the semiconductor device 102. The pin securing block 101 of the socket is attached, using screws, or the like, to a wiring substrate 107 which is connected to the measurement apparatus.

The probe pin 108 includes a cylinder 110, a compression spring 111 and a plunger 109 which is the tip portion. The tip of the plunger 109 has a concave cup shape or a concave crown shape having a diameter larger than the diameter of a solder ball 120 which is a hemispherical electrode terminal of the semiconductor device 102, and the concave-shaped portion is facing the solder ball 120.

As shown in FIG. 1, the pin securing block 101 is a frame that is rectangular as seen from above, and the top plate 105, which includes a guide portion 113 allowing the semiconductor device 102 to seat thereon and positioning the semiconductor device 102 by the outer shape thereof, is placed above the pin securing block 101. The pin securing block 101 is provided with a restriction hole 106 for positioning the pressing head 103. A pressure-receiving portion 104 located in the uppermost portion of the top plate 105 is provided in the upper portion of the guide portion 113.

An elastic member 112 for vertically movably supporting the top plate 105 is provided between the pin securing block 101 and the top plate 105. The top plate 105 includes a plurality of through holes 114 provided in a lattice pattern which receive tip portions of the plungers 109 of the probe pins 108, and the through holes 114 accommodate the solder balls 120.

As shown in FIG. 1, the pressing head 103 is vertically movable with respect to the pin securing block 101. The pressing head 103 includes a position restriction pin 115 which fits into the restriction hole 106 of the pin securing block 101. A suction section 121 for sucking onto the semiconductor device 102 through depressurization is provided in a portion of the pressing head 103 that is to be in contact with the semiconductor device 102.

The functions of the above configuration will now be described.

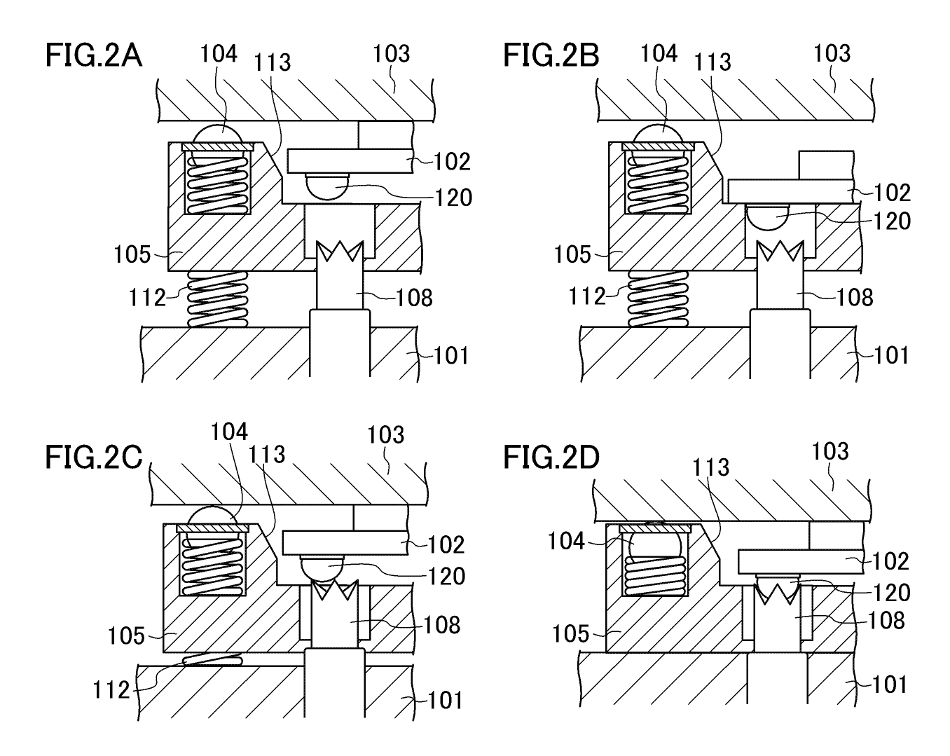

As shown in FIG. 2A, the surface of the semiconductor device 102 opposite to the surface on which the solder balls 120 are placed is sucked by the suction section 121 of the pressing head 103, and the semiconductor device 102 lowers together with the pressing head 103. Next, as shown in FIG. 2B, when the pressing head 103 is lowered to a predetermined position, the suction is turned OFF to let the semiconductor device 102 free-fall and seat on the top plate 105, and the semiconductor device 102 is positioned by the guide portion 113 of the top plate 105. The guide portion 113 has a tapered shape such that the area of the opening on the upper side thereof increases in the upward direction, and the semiconductor device 102 is positioned at an appropriate position by this tapered portion. In this process, the pressing head 103 and the top plate 105 are not in contact with each other, and the solder ball 120 of the semiconductor device 102 and the tip of the probe pin 108 are not in contact with each other.

Then, as the pressing head 103 is allowed to lower, the restriction pin 115 of the pressing head 103 of FIG. 1 fits into the restriction hole 106 provided in the pin securing block 101 for positioning, before the pressing head 103 contacts the pressure-receiving portion 104 protruding from the upper portion of the top plate 105.

As shown in FIG. 2C, as the pressing head 103 is further lowered, the pressing head 103 contacts and applies a downward pressure on the pressure-receiving portion 104, which is located in the uppermost portion of the top plate 105, thereby pressing down the top plate 105. Then, as the elastic member 112 is shortened, the main body portion of the top plate 105 on which the pressure-receiving portion 104 is placed lowers, but the pressing head 103 is not in contact with the semiconductor device 102.

As the top plate 105 is pressed down, the tip portion of the probe pin 108 relatively moves up in the through hole 114, and the plunger 109 which is the tip of the probe pin 108 contacts the solder ball 120 which is an electrode of the semiconductor device 102. Then, the solder ball 120 is guided by the concave-shaped portion at the tip of the probe pin 108 into the concave-shaped portion, thereby positioning the probe pin 108 and the solder ball 120 with each other. That is, since the solder ball 120 is hemispherical and the tip of the plunger 109 has a concave shape, even if the central axis in the vertical direction of the solder ball 120 and the central axis in the vertical direction of the concave-shaped portion at the tip of the plunger 109 are not initially aligned with each other, the semiconductor device 102 moves horizontally in such a direction that the central axes are aligned with each other as the semiconductor device 102 lowers. Note that it can also be said that such a mechanism moves the semiconductor device 102 horizontally. Since the pressing head 103 is not in contact with the semiconductor device 102 at this point, the semiconductor device 102 lowers only by its own weight, and therefore the movement in the horizontal direction is done easily.

If the pressing head 103 is further lowered after the solder ball 120 has been guided into and positioned in the tip shape of the probe pin 108, the spring of the pressure-receiving portion 104 protruding from the upper portion of the top plate 105 is compressed, as shown in FIG. 2D. Then, after the top plate 105 is pressed down by a predetermined amount in total, the lower surface of the pressing head 103 contacts the upper portion of the semiconductor device 102, and a pressure is applied from the solder ball 120 of the semiconductor device 102 toward the probe pin 108 so that the solder ball 120 of the semiconductor device 102 and the probe pin 108 can reliably be brought into electric contact with each other, thus allowing for reliable measurement of the electric characteristics.

Note that although the pressure-receiving portion 104 is provided protruding from the upper portion of the guide portion of the top plate 105 and the top plate 105 is pressed down with the pressing head 103 in the present embodiment, another possible configuration includes, for example, a mechanism using a powered mechanism or an air cylinder for lowering the top plate 105 as it detects the semiconductor device 102 having been accommodated in the top plate 105.

The mechanism of the pressure-receiving portion 104 protruding from the upper portion of the top plate 105 may be attached to the portion of the pressing head 103 instead of the upper surface of the top plate 105. When attached to the pressing head 103, this mechanism becomes the first pressing portion which first contacts, and starts pushing, the top plate 105, and the second pressing portion of the pressing head 103 contacts and presses the semiconductor device 102 after the amount by which the top plate 105 is pushed down reaches a predetermined amount.

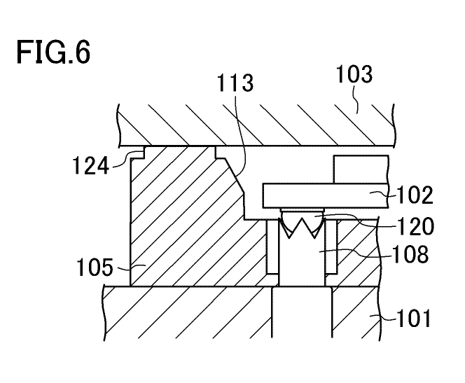

As shown in FIG. 6, the pressure-receiving portion 104 protruding from the upper portion of the top plate 105 may be a simple protrusion 124 with no spring mechanism. In such a case, when the top plate 105 is pressed down to the lower limit by the pressing head 103, the semiconductor device 102 may possibly be supported only by the probe pin 108 without being accommodated by the top plate 105. However, even in such a state, since the semiconductor device 102 is placed on the probe pin 108, the solder ball 120 and the probe pin 108 can be brought into contact with each other with no misalignment unless there is a disturbance such as wind.

### Embodiment 2

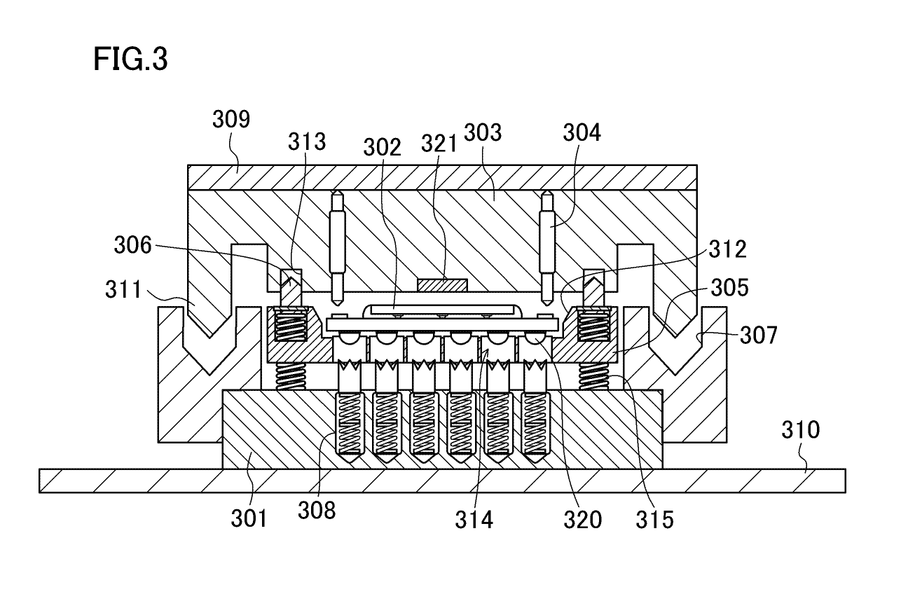

A testing apparatus of Embodiment 2 is an electric characteristics testing apparatus of a PoP (Package on Package) semiconductor device shown in FIG. 3, which has electrodes both on the upper surface and on the lower surface.

The semiconductor testing apparatus of the present embodiment includes first probe pins 308, a pin securing block 301 for holding the first probe pins, a top plate (support plate) 305 including a floating mechanism, second probe pins 304 to be in electric contact with the upper surface electrodes of a PoP semiconductor device 302, and a pressing head 303 for pressing the semiconductor device 302, the pressing head 303 holding the second probe pins 304 and including a first wiring substrate 309 connected to the measurement apparatus.

The pin securing block 301 of the semiconductor testing apparatus is attached, using screws, or the like, to a second wiring substrate 310 which is connected to the measurement apparatus. The first probe pin 308 includes a cylinder, a compression spring and a plunger, as in Embodiment 1. The tip of the plunger has a concave cup shape or a concave crown shape having a diameter larger than the diameter of a solder ball 320. The second probe pin 304 also includes a cylinder, a compression spring and a plunger, but the tip thereof has a cone shape.

As shown in FIG. 3, the pin securing block 301 is a frame that is rectangular as seen from above, and a top plate 305, which includes a guide portion 312 allowing the semiconductor device 302 to seat thereon for positioning, is placed above the pin securing block 301. A protruding sliding mechanism (pressure-receiving portion) 306 is provided in the upper portion of the guide portion 312, and the pressing head 303 includes a restriction hole 313 whose position is restricted by the protruding sliding mechanism 306. The pin securing block 301 includes a restriction hole 307 for positioning the pressing head 303, and the pressing head 303 includes a pin (restriction pin) 311 which fits into the restriction hole 307. A suction section 321 for sucking onto the semiconductor device 302 is provided in a portion of the pressing head 303 that is to be in contact with the semiconductor device 302.

An elastic member 315 for vertically movably supporting the top plate 305 as in Embodiment 1 is provided between the pin securing block 301 and the top plate 305. The top plate 305 includes a plurality of through holes 314 provided in a lattice pattern which receive tip portions of the first probe pins 308 so that the tips of the first probe pins 308 can be accommodated in the top plate 305, and the solder balls 320 of the semiconductor device 302 are also accommodated in the through holes 314 of the top plate 305.

The functions of the above configuration will now be described.

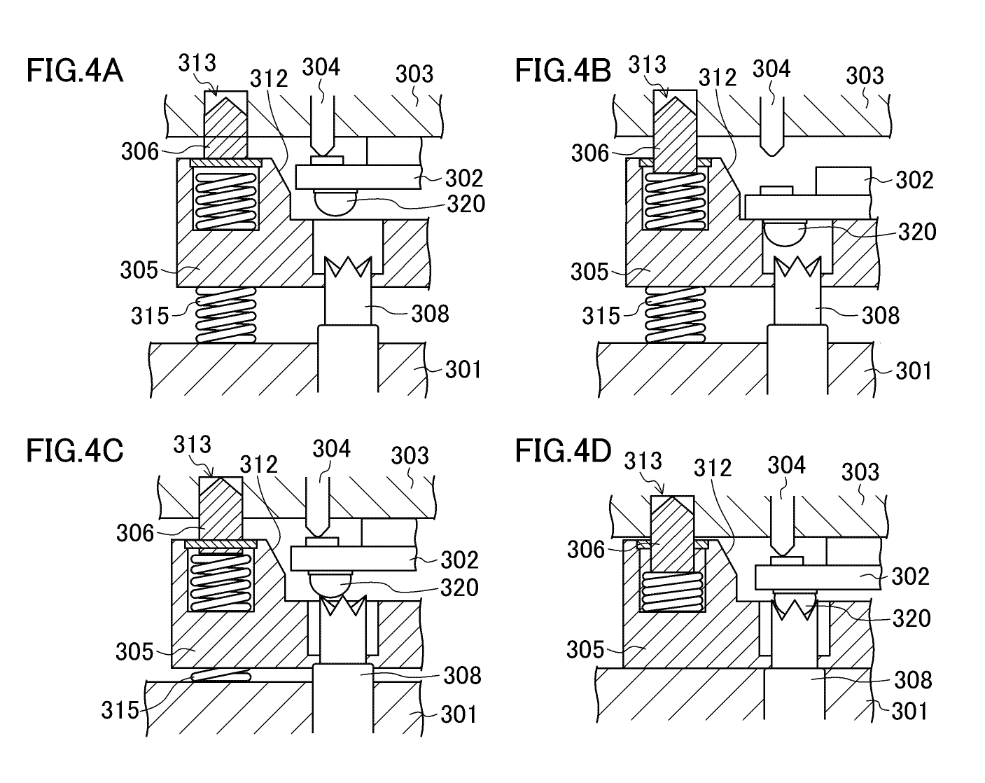

As shown in FIG. 4A, the surface of the semiconductor device 302 opposite to the surface on which the solder balls 320 are placed is sucked by the suction section 321 of the pressing head 303, and the semiconductor device 302 lowers together with the pressing head 303. First, the restriction pin 311 fits into and is positioned in the restriction hole 307. Next, the sliding mechanism 306, which is located in the uppermost portion of the top plate 305 and is protruding in a pin shape, fits into the restriction hole 313. When the pressing head 303 is lowered to a predetermined position, the suction is turned OFF to let the semiconductor device 302 free-fall and seat on the top plate 305, as shown in FIG. 4B, thereby positioning the semiconductor device 302 by the guide portion 312 of the top plate 305. The guide portion 312 has a tapered shape such that the opening area thereof increases in the upward direction, and the semiconductor device 302 is positioned at an appropriate position by this tapered portion. In this process, the pressing head 303 is not pressing down the top plate 305, and the solder ball 320 of the semiconductor device 302 is not in contact with the tip of the first probe pin 308.

As the pressing head 303 is further lowered, the pointy end of the sliding mechanism 306 hits the deep end (bottom) of the restriction hole 313 so that the pressing head 303 applies a downward pressure on the top plate 305, thus pressing down the top plate 305. As the elastic member 315 is shortened, the main body portion of the top plate 305 on which the sliding mechanism 306 is placed lowers, but the pressing head 303 is not in contact with the semiconductor device 302.

As the top plate 305 is pressed down, the tip portion of the first probe pin 308 relatively moves up in the through hole 314, and the tip of the first probe pin 308 contacts the solder ball 320 which is an electrode of the semiconductor device 302, as shown in FIG. 4C. Then, the solder ball 320 is guided by the concave-shaped portion at the tip of the first probe pin 308 into the concave-shaped portion, thereby positioning the first probe pin 308 and the solder ball 320 with each other. That is, since the solder ball 320 is hemispherical and the tip of the first probe pin 308 has a concave-shaped portion, even if the central axis of the solder ball 320 in the vertical direction and that of the concave-shaped portion at the tip of the first probe pin 308 are not initially aligned with each other, the semiconductor device 302 moves horizontally in such a direction that the central axes are aligned with each other as the semiconductor device 302 lowers. Note that it can also be said that such a mechanism moves the semiconductor device 302 horizontally. Since the pressing head 303 is not in contact with the semiconductor device 302 at this point, the semiconductor device 302 lowers only by its own weight, and therefore the movement in the horizontal direction is done easily. Thus, the first probe pin 308 and the second probe pin 304 are positioned with respect to the upper surface and lower surface electrodes of the semiconductor device 302.

If the pressing head 303 is further lowered, the spring of the sliding mechanism 306 of the top plate 305 is compressed so as to being the second probe pin 304 into contact with the upper surface electrode of the semiconductor device 302. If the pressing head 303 is further lowered, the lower surface of the pressing head 303 contacts the upper portion of the semiconductor device 302, as shown in FIG. 4D, thereby applying a pressure on the solder ball 320 of the semiconductor device 302 and the first probe pin 308, thereby reliably bringing the upper surface electrode of the semiconductor device 302 into electric contact with the second probe pin 304 and the solder ball 320 of the semiconductor device 302 into electric contact with the first probe pin 308, thus allowing for reliable measurement of the electric characteristics.

As in Embodiment 1, the sliding mechanism 306 protruding from the upper portion of the top plate 305 may be attached to the pressing head portion instead of the upper surface of the top plate 305. The sliding mechanism protruding from the upper portion of the top plate may be a protrusion with no sliding mechanism, as in Embodiment 1.

In Embodiment 1, the vertical movement of the pressing head 103 is position-restricted only with the restriction pin 115, and there is therefore a limit on increasing the positional precision of the pressing head 103 with respect to the semiconductor device 102 as it is likely influenced by the cumulative tolerance from the semiconductor device 102. In Embodiment 2, since the pressing head 303 is eventually positioned by the restriction pin 306 which is close to the semiconductor device 302, it is possible to sufficiently increase the positional precision of the pressing head 303 with respect to the semiconductor device 302, and the positional precision can be made higher than that in Embodiment 1.

As described above, according to the present invention, probe pins can be contacted to solder balls of a semiconductor device with narrow terminal intervals with desirable positional precision, and it is possible to ensure stable electric contact therebetween, without attaching a sensor for recognizing the position of the semiconductor device.

It is also possible to improve the positional precision of the device without narrowing the clearance between the device outer shape and the guide portion of the top plate, and it is possible to prevent the device from being stuck in the top plate.

As described above, the semiconductor testing apparatus of the present invention is useful as a testing apparatus such as a BGA-type semiconductor device because the hemispherical electrode terminals of the semiconductor device can be reliably fitted into the concave-shaped portions of the probe tips to reliably measure the electric characteristics.

What is claimed is:

1. A semiconductor testing apparatus for testing electric characteristics of a semiconductor device having a plurality of hemispherical electrode terminals on one surface thereof, comprising:
a support plate vertically movably supported by an elastic member, supporting a side of the one surface of the semiconductor device, and having through holes for accommodating the hemispherical electrode terminals;
a probe pin securing block placed under the support plate;
a plurality of probe pins secured to the probe pin securing block and having concave-shaped tips facing the hemispherical electrode terminals of the semiconductor device supported by the support plate; and
a vertically movable pressing head placed over the support plate for applying a downward pressure on the support plate,
wherein after the support plate is lowered by a predetermined amount by the downward pressure from the pressing head, the pressing head contacts the semiconductor device and applies a downward pressure thereon.

2. The semiconductor testing apparatus of claim 1, wherein the pressing head includes a suction section for sucking onto a surface of the semiconductor device opposite to the one surface, and applies the downward pressure on the support plate after allowing the semiconductor device to fall onto the support plate by releasing suction.

3. The semiconductor testing apparatus of claim 1, wherein
the support plate includes a main body portion on which the semiconductor device is placed, and a pressure-receiving portion which is attached to the main body portion and to be in contact with the pressing head to receive the downward pressure, and
the pressure-receiving portion maintains a gap between the pressing head and the semiconductor device while the main body portion is lowered by the predetermined amount by receiving the downward pressure from the pressing head.

4. The semiconductor testing apparatus of claim 1, wherein
the pressing head includes a first pressing portion to be in contact with the support plate for pressing down the support plate, and a second pressing portion to be in contact with the semiconductor device for applying a downward pressure on the semiconductor device, and
the first pressing portion maintains a gap between the second pressing portion and the semiconductor device while the support plate is lowered by the predetermined amount.

5. The semiconductor testing apparatus of claim 3, wherein the pressure-receiving portion includes a positioning mechanism with respect to the pressing head.

6. A testing method using the semiconductor testing apparatus of claim 1, comprising the steps of:
placing the semiconductor device on the support plate so that the hemispherical electrode terminals are accommodated in the through holes;
(A) lowering the support plate by applying a pressure thereon using the pressing head while maintaining a gap between the pressing head and the semiconductor device; and
applying a downward pressure on the semiconductor device using the pressing head so as to ensure an electric conduction between the probe pins and the hemispherical electrode terminals, wherein
in the step (A), the semiconductor device is moved horizontally so that the hemispherical electrode terminals fit into the concave-shaped tips of the probe pins.
